(19) United States
(12) Patent Application Publication
(10) Pub. No.: US 2024/0175474 A1
(43) Pub. Date: May 30, 2024

(54) DEVICES, SYSTEMS, AND METHODS FOR DAMPENING VIBRATIONS AT A COMPUTING DEVICE

(71) Applicant: Microsoft Technology Licensing, LLC, Redmond, WA (US)

(72) Inventors: Rick Chun Kit CHEUNG, Lynnwood, WA (US); Luke Thomas GREGORY, Mercer Island, WA (US)

(21) Appl. No.: 18/072,206

(22) Filed: Nov. 30, 2022

(51) Int. Cl. F16F 7/10; G06F 1/20; H05K 7/20

(52) U.S. Cl. CPC F16F 7/10; G06F 1/206; H05K 7/2039; F16F 2222/08

(57) ABSTRACT

A vibration reduction system may include a base. A vibration reduction system may include a computing component connected to the base. The computing component has a vibration frequency. A vibration reduction system may include a tuned mass dampener having a tuned frequency to reduce a magnitude of vibration of the computing component.

### CROSS-REFERENCE TO RELATED APPLICATIONS

N/A.

### BACKGROUND

Modern trends in computing have decreased processor size, increased processor capacity, and increased processor density. This has resulted in additional components on computing devices of the same size. During operation, the increased processor capacity and/or density may generate additional heat. The additional heat may involve larger and/or additional thermal management devices. As they become larger, the thermal management devices may extend further above the base of the computing device.

### BRIEF SUMMARY

In some aspects, the techniques described herein relate to a computing system. The computing system includes a base. A computing component is connected to the base. The computing component has a vibration frequency. A tuned mass dampener has a tuned frequency to reduce a magnitude of vibration of the computing component.

In some aspects, the techniques described herein relate to a method of manufacturing a computing device. The method includes determining a natural vibration frequency of a computing component secured to a base. Based on the natural vibration frequency, a tuning frequency of a tuned mass dampener is determined. The tuned mass dampener is prepared having the tuning frequency. The tuned mass dampener is secured to the computing device.

This summary is provided to introduce a selection of concepts that are further described below in the detailed description. This summary is not intended to identify key or essential features of the claimed subject matter, nor is it intended to be used as an aid in limiting the scope of the claimed subject matter.

Additional features and advantages of embodiments of the disclosure will be set forth in the description which follows, and in part will be obvious from the description, or may be learned by the practice of such embodiments. The features and advantages of such embodiments may be realized and obtained by means of the instruments and combinations particularly pointed out in the appended claims. These and other features will become more fully apparent from the following description and appended claims, or may be learned by the practice of such embodiments as set forth hereinafter.

### BRIEF DESCRIPTION OF THE DRAWINGS

In order to describe the manner in which the above-recited and other features of the disclosure can be obtained, a more particular description will be rendered by reference to specific implementations thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example implementations, the implementations will be described and explained with additional specificity and detail through the use of the accompanying drawings in which:

FIG. 1 is a representation of a computing system having a computing component connected or secured to a base, according to at least one embodiment of the present disclosure;

FIG. 2 is a representation of a computing device having a computing component connected to a base, according to at least one embodiment of the present disclosure;

FIG. 3 are representations of vibration profiles, according to at least one embodiment of the present disclosure;

FIG. 4 is a representation of a side-view of a computing device, according to at least one embodiment of the present disclosure;

FIG. 5 is a representation of a side-view of a computing device, according to at least one embodiment of the present disclosure;

FIG. 6 is a representation of a side-view of a computing device, according to at least one embodiment of the present disclosure; and

FIG. 7 is a flowchart of a method for manufacturing a computing device, according to at least one embodiment of the present disclosure.

### DETAILED DESCRIPTION

This disclosure generally relates to devices, systems, and methods for reducing the magnitude of vibrations of a computing component of a computing device. As computing devices increase in processing capacity, the lateral layout of computing device may remain the same and/or may not increase at the same rate. Indeed, additional computing components may be added to the same base. This may result in an increase in the vertical layout of the computing device. For example, as the processing capacity of a computing device increases, the associated heat generation may increase. A thermal management device to absorb and/or reduce the heat of the processor may extend vertically further above the base. This may change the vibration pattern or vibration profile of the computing device.

During packaging, shipping, handling, operation, or other activities, the computing device may be subject to operational vibrations. In some situations, as the vibration pattern or vibration profile of the computing device changes, the operational vibrations may at least partially overlap a natural vibration frequency of the computing device. In some situations, the operational vibrations may at least partially overlap the natural vibration frequency for a period of time. Subjecting the computing device to the natural vibration frequency may cause damage to the computing device. For example, components of the computing device may crack, be dislodged, be otherwise damaged, and combinations thereof. In some situations, the damaged computing device may be experience decreased performance and/or a decreased operational lifetime. In some situations, the damaged computing device may be irreparable, thereby causing the damaged computing device to be discarded and/or recycled.

In accordance with at least one embodiment of the present disclosure, a tuned mass dampener is secured to the computing device. The tuned mass dampener may have a tuned frequency that may reduce a magnitude of the vibration of the computing component. This may help to reduce or prevent damage to the computing device during packaging, shipping, handling, operation, or other activities that to which the computing device is subjected. For example, by reducing the magnitude of the vibration experienced by the computing device, the forces experienced by the components connected to the computing device may be reduced. Reducing the forces on the computing components may help to reduce damage incurred by them. This may help to improve the reliability of the computing device.

As illustrated by the foregoing discussion, the present disclosure utilizes a variety of terms to describe features and advantages of the vibration reduction system. Additional detail is now provided regarding the meaning of such terms. For example, as used herein, the term “computing component” refers to any component on a computing device. In particular, the term “computing component” may refer to a processor, a thermal management device, memory, an antenna, a pump, any other computing component, and combinations thereof.

As used herein, the term “vibration profile” may include any vibrational property of an element. For example, the vibration profile may include a relationship between frequency and displacement. In some examples, the vibration profile may include one or more resonant frequencies. A resonant frequency, or a natural vibration frequency, may be a frequency or range of frequencies at which the displacement of the vibrating element may be maximized, or locally maximized. In some embodiments, the vibration profile may include a single resonant frequency. In some embodiments, the vibration profile may include multiple resonant frequencies.

As used herein, the term “tuned frequency” may include a resonant frequency for a tuned mass dampener. For example, the tuned frequency may be a natural vibration frequency for a tuned mass dampener. In some examples, the tuned frequency may be adjustable. For example, the components of the tuned mass dampener may be adjusted to adjust the tuned frequency. The tuned frequency may be adjustable based on adjustments to the width, length, mass, or other elements of the tuned mass dampener.

As used herein, a “thermal management device” may include any computing component that is configured to transfer heat away from a heat-generating component. For example, a thermal management device may include one or more of a vapor chamber, a cold plate, heat-radiating fins, a fan, any other thermal management device, and combinations thereof.

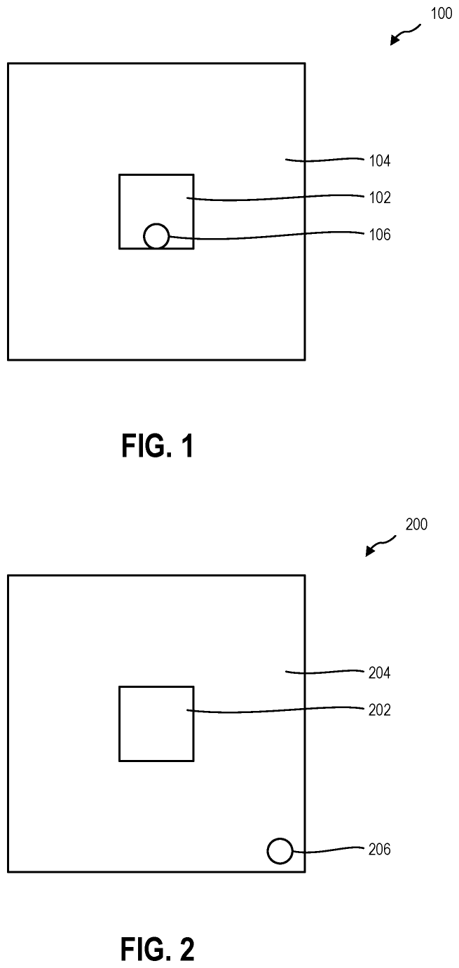

FIG. 1 is a representation of a computing system 100 having a computing component 102 connected or secured to a base 104, according to at least one embodiment of the present disclosure. The base 104 may be any type of base of a computing device. For example, the base 104 may include a printed circuit board, a silicon base, a base of a bare die, any other base, and combinations thereof. For ease of illustration, other computing components of the computing system 100 have not been shown. However, it should be understood that the computing system 100 may include any number of computing components. As discussed herein, the computing component 102 may include any type of computing component, such as a thermal management device. The computing component 102 may extend vertically from the base 104. For example, the computing component 102 may extend into the page.

The computing system 100 may be subject to operating vibrations. The operating vibrations may be due to any activity, such as packing, shipping, handling, operation, or other activities. The operating vibrations may have an operating vibration profile that is experienced during operations. The operating vibration profile may include a relationship between frequency and magnitude experienced during operations. In some embodiments, the operating vibration profile may include time-based operating information. For example, the operating vibration profile may include a length of time spent within a particular frequency or range of frequencies. In some embodiments, the operating vibrations are passed to the computing system 100. Put another way, the computing system 100 may experience the operating vibrations. The frequency of the vibrations may represent the number of vibrations that occur over a period of time, typically represented in Hz. The magnitude of the vibrations may represent the displacement of the vibrating element. The magnitude of the vibrations may be the amplitude of the vibration profile.

The computing system 100 and/or the computing component 102 may a component vibration profile with a natural vibration frequency. The natural vibration frequency may be a harmonic frequency of the computing system 100 and/or the computing component 102. At the natural vibration frequency, the displacement of the computing component 102 may be maximized. In some situations, vibrating at the natural vibration frequency may increase the likelihood of damage to the base 104 and/or the computing component 102.

In some situations, the operating vibration profile may overlap the natural vibration frequency. Because the computing system 100 and/or the computing component 102 experience the operating vibration profile, in some situations, the computing system 100 and/or the computing component 102 may experience vibrations at or near the natural vibration frequency. This may cause the computing system 100 and/or the computing component 102 to become damaged.

In accordance with at least one embodiment of the present disclosure, the computing system 100 includes a tuned mass dampener 106. The tuned mass dampener 106 may help to reduce the magnitude of the displacement of the computing component 102 during vibrations. Reducing the magnitude of the displacement may help to reduce damage to the computing component 102 during vibrations. In this manner, the tuned mass dampener 106 may help to reduce damage to the computing component 102.

The tuned mass dampener 106 may be secured to the computing component 102 and/or the base 104. Securing the tuned mass dampener 106 to the computing component 102 and/or the base 104 may transfer vibrational energy between the tuned mass dampener 106 and the computing component 102 and/or the base 104. For example, vibrations of the base 104 may cause the tuned mass dampener 106 to vibrate. In some embodiments, the tuned mass dampener 106 may dampen at least a portion of the vibrational energy from the computing component 102 and/or the base 104. This may help to reduce the vibration of the computing component 102 and/or the base 104, thereby reducing the likelihood of damage to the computing component 102 and/or the base 104.

The tuned mass dampener 106 has a tuning frequency. At the tuning frequency, the tuned mass dampener 106 may vibrate with a maximum displacement. In some examples, at the tuning frequency, the tuned mass dampener 106 may dampen a maximum amount of vibrational energy. In some embodiments, the tuning frequency may be approximately the same as the natural vibration frequency of the computing component 102 and/or the base 104. When the tuned mass dampener 106 is secured to the computing component 102 and/or the base 104, the tuned mass dampener 106 may dampen the vibrations of the computing component 102 and/or the base 104. A tuning frequency that is approximately the same as the natural vibration frequency dampen vibrations at the natural vibration frequency. This may reduce the maximum displacement of vibrations of the computing component 102 and/or the base 104, thereby reducing and/or preventing damage to the computing component 102 and/or base 104.

In the embodiment shown, the tuned mass dampener 106 is located at or proximate to the computing component 102. Locating the tuned mass dampener 106 at or proximate to the computing component 102 may help to localize the dampening effect of the tuned mass dampener 106 to the computing component 102. In some embodiments, the tuned mass dampener 106 may be secured to the base 104. In some embodiments, the tuned mass dampener 106 is secured to the computing component 102. In some embodiments, the tuned mass dampener 106 is vibrationally fixed to the computing component 102. Put another way, when the base 104 and/or the computing component 102 vibrate, the tuned mass dampener 106 may vibrate too.

While the tuned mass dampener 106 is shown located at or proximate the computing component 102, it should be understood that the tuned mass dampener 106 may be located at any location on the computing system 100. Computing systems 100 may include multiple computing components 102 that may be located in close proximity to each other. The tuned mass dampener 106 may be placed on the base 104 where there is room for it. Put another way, the tuned mass dampener 106 may be placed on the base 104 where it may not interfere with the placement and/or operation of a computing component 102.

FIG. 2 is a representation of a computing device 200 having a computing component 202 connected to a base 204, according to at least one embodiment of the present disclosure. A tuned mass dampener 206 is connected to the base 204. In the embodiment shown the tuned mass dampener 206 is connected to the base 204 at a location that is removed from the computing component 202. Put another way, the tuned mass dampener 206 is not adjacent or proximate to the computing component 202. As discussed herein, the computing component 202 may be secured to the base 204. The tuned mass dampener 206 is secured to the base 204. When the base 204 experiences vibrations, the vibrations may be passed to the tuned mass dampener 206. The tuned mass dampener 206 may dampen the vibrations, thereby reducing or preventing damage to the computing component 202 or the base 204.

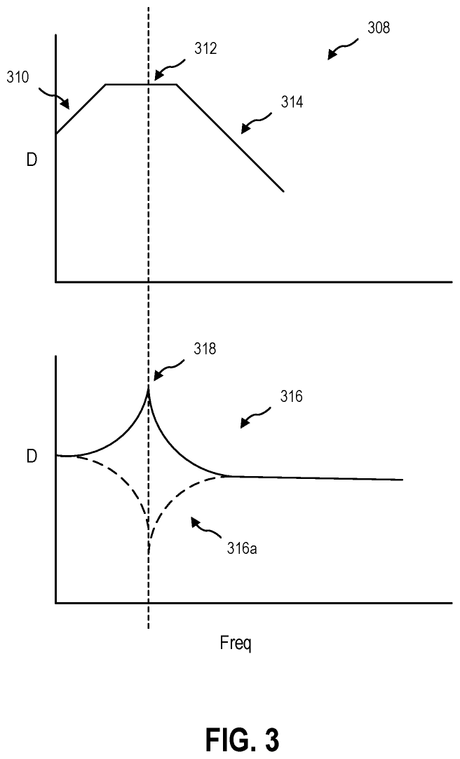

FIG. 3 is a representation of vibration profiles having displacement D on the vertical axis and frequency on the horizontal axis, according to at least one embodiment of the present disclosure. An operating vibration profile 308 may show the vibration profile experienced during packaging, shipping, handling, operation, any other activity, and combinations thereof. For example, the operating vibration profile 308 may be a profile experienced by a computing device during shipping.

The operating vibration profile 308 may include an operating ramp up 310. The operating ramp up 310 may be low-frequency vibrations, often experienced during startup of an operation, such as startup of an engine, acceleration, and so forth. The operating vibration profile 308 may further include an operating peak zone 312. The operating peak zone 312 may be a range of frequencies at which the displacement D is maximized. As may be seen, the operating peak zone 312 may occur over a range of frequencies. While the operating peak zone 312 is shown with a constant displacement, it should be understood that the operating peak zone 312 may have a range or a zone of displacements.

The operating vibration profile 308 may include a high frequency zone 314. In the high frequency zone 314, the displacement may be reduced. For example, as the frequency increases, the displacement may decrease. In some embodiments, the high frequency zone 314 may be based on displacements that are less than the threshold displacement.

A device vibration profile 316 may be the vibration profile of a computing device and/or one or more computing elements of the computing device. The device vibration profile 316 may be a representation of the displacement of a computing device and/or a computing component secured to the computing device. The device vibration profile 316 may include one or more natural vibration frequencies 318. The natural vibration frequency 318 may be a peak in the magnitude of the displacement. For example, the natural vibration frequency 318 may be a harmonic frequency of the computing device and/or a computing component secured to the computing device. In some situations, the magnitude of the displacement at the natural vibration frequency 318 may cause damage to the computing device.

The resonant frequency of a system may be related to the mass and the spring constant, as shown in Eq. 1:

$$Freq = \sqrt{\frac{k}{m}} \qquad Eq . 1$$

where k is the spring constant and m is mass. As may be seen, increasing the mass of a body may reduce the frequency of the resonant frequency. As computing devices increase in processing power and complexity, the cooling system may have an increased cooling capacity to maintain the operating temperature of the computing device. This may result in an increase in the mass of the thermal management device. The thermal management device may be rigidly secured to the base with one or more fasteners, such as screws or bolts. The tightness of the connection and/or the material of the fastener may determine the spring constant k. As may be seen in Eq. 1, for an unchanged spring constant k, increasing the mass of the thermal management device may reduce the natural vibration frequency 318 of the thermal management device. Reducing the natural vibration frequency 318 of the thermal management device may cause the thermal management device to be more likely to experience the natural vibration frequency 318 and make the thermal management device more likely to be damaged.

As discussed herein, the operating peak zone 312 may occur over a range of displacements. In some embodiments, the operating peak zone 312 may occur over frequencies associated with a displacement D above a threshold displacement. In some embodiments, the threshold displacement may be based on a displacement of the computing device that may cause damage to the computing device. Put another way, the threshold displacement may be the displacement above which damage may occur to the computing device and/or the computing component. For example, the threshold displacement may be based on the natural vibration frequency 318 of the device vibration profile 316. In some situations, the operating peak zone 312 be a sustained vibrational pattern. For example, the operating peak zone 312 may occur during shipping, travel, or other activity.

In some embodiments, the computing device may be subjected to the operating vibration profile 308. As discussed herein, as the mass of thermal management devices has increased, the frequency of the natural vibration frequency 318 may be reduced. This may cause the operating peak zone 312 to overlap the natural vibration frequency 318. When the operating peak zone 312 overlaps the natural vibration frequency 318, the computing device may experience the natural vibration frequency 318. This may cause damage to one or more of the computing components of the computing device.

As discussed herein, a tuned mass dampener may be secured to the computing device. The tuned mass dampener may have a tuned frequency that is the same as or approximately the same as the natural vibration frequency 318. The tuned mass dampener may reduce the maximum displacement of the computing component of the computing device. In some embodiments, the tuned mass dampener adjusts the device vibration profile 316 to a modified device vibration profile 316a. The modified device vibration profile 316a may reduce the maximum displacement at the natural vibration frequency 318. For example, as discussed herein, the tuned mass dampener may dampen the vibrations experienced by the computing device. The motion of the tuned mass dampener may at least partially cancel out or otherwise dampen the vibrations experienced at the natural vibration frequency 318. This may reduce the magnitude of the vibrations at the natural vibration frequency 318. In this manner, the tuned mass dampener may reduce or prevent damage to the computing device.

In some embodiments, the tuned frequency may be within a frequency percentage of the natural vibration frequency 318. In some embodiments, the frequency percentage (e.g., the natural vibration frequency 318 minus the tuned frequency divided by the natural vibration frequency 318) may be in a range having an upper value, a lower value, or upper and lower values including any of −30%, −25%, −20%, −15%, −10%, −5%, 0%, 5%, 10%, 15%, 20%, 25%, 30% or any value therebetween. For example, the frequency percentage may be greater than −30%. In another example, the frequency percentage may be less than 30%. In yet other examples, the frequency percentage may be any value in a range between −30% to 30%. In some embodiments, it may be critical that the frequency percentage is between −10% and 10% to dampen the vibrations of the computing component and reduce vibrational damage. A negative frequency percentage may represent a higher tuned frequency than the natural vibration frequency 318. A positive frequency percentage may represent a lower tuned frequency than the natural vibration frequency 318. A frequency percentage of zero may represent a tuned frequency that is the same as the natural vibration frequency 318.

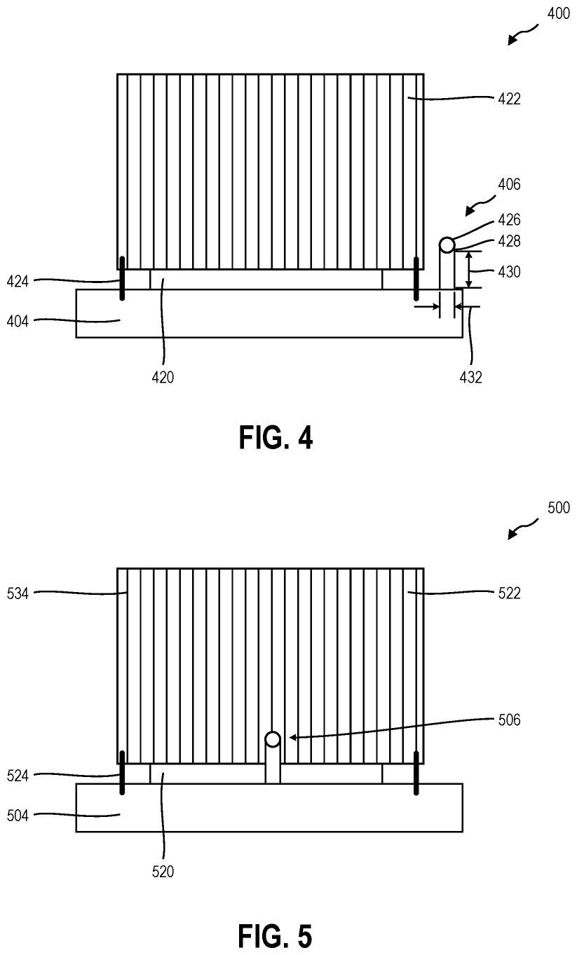

FIG. 4 is a representation of a side-view of a computing device 400, according to at least one embodiment of the present disclosure. A processor 420 is connected to a base 404. A thermal management device 422 is thermally connected to the processor 420. The thermal management device 422 may be secured to the base 404 with one or more fasteners 424. As discussed herein, as the processing capacity and/or density of the processor 420 increases, the thermal management device 422 may extend vertically (e.g., toward the top of the page) above the base 404. In some embodiments, the mass of the thermal management device 422 may increase.

As discussed herein with respect to Eq. 1, as the mass of the thermal management device 422 increases, the natural vibration frequency of the thermal management device 422 may be reduced. This may make the thermal management device 422 more susceptible to vibrational damage. The spring constant k may be based on the material and/or the tension of the fasteners 424.

In accordance with at least one embodiment of the present disclosure, a tuned mass dampener 406 may be secured to the computing device 400. For example, in the embodiment shown, the tuned mass dampener 406 is secured to the base 404. The tuned mass dampener 406 may include a tuning mass 426 connected to a tuning support 428. The tuning support 428 may be secured to the base 404. As the computing device 400 vibrates, the connection between the base 404 and the tuned mass dampener 406 may cause the tuning mass 426 to vibrate.

In the embodiment shown, the tuned mass dampener 406 is located adjacent to the thermal management device 422. For example, the tuned mass dampener 406 is located next to the thermal management device 422. The tuned mass dampener 406 may be secured to the base 404. Because the tuned mass dampener 406 and the thermal management device 422 are secured to the base 404, the dampening effects of the tuned mass dampener 406 may transfer to the thermal management device 422. As discussed herein, the tuned mass dampener 406 may be located at any location relative to the thermal management device 422.

The tuning mass 426 may vibrate with a tuned frequency. With reference to Eq. 1, the tuned frequency may be based on dampener properties of the tuned mass dampener 406, such as the mass of the tuned mass dampener 406 and the spring constant k of the tuned mass dampener 406. The dampener properties may include the mass of the tuned mass dampener 406 may be adjusted by changing the size of the tuning mass 426 and/or the tuning support 428. The dampener properties may include the spring constant k may be adjusted by changing the dimensions of the tuning support 428. For example, the spring constant k may be adjusted by changing support dimensions of the tuned mass dampener 406, such as a support height 430 of the tuning support 428. In some examples, the spring constant k may be adjusted by changing other support dimensions, such as a support width 432 of the tuning support 428. In some examples, the spring constant k may be adjusted by changing a material of the tuning support 428. In some examples, the spring constant k may be adjusted by changing any combination of the dampener properties, including the support dimensions (e.g., the support height 430, the support width 432), the material of the tuning support 428, or any other property of the tuning support 428. As discussed herein, the tuned mass dampener 406 may be adjusted by adjusting the dampener properties.

The tuned mass dampener 406 may have a tuned frequency that is the same as or approximately the same as the natural vibration frequency of the thermal management device 422. In some embodiments, the tuned frequency of the tuned mass dampener 406 is designed or prepared to have the same or approximately the same frequency as the natural vibration frequency of the thermal management device 422. In some embodiments, the tuned frequency may be adjusted by adjusting the dampener properties.

In some embodiments, an operator may determine the natural vibration frequency of the thermal management device 422. For example, the operator may determine the natural vibration frequency using one or more vibration models. A vibration model may include a computer model that may determine the device vibration profile of the computing device 400. In some embodiments, the vibration model may determine a component vibration profile that is specific to the thermal management device 422. In some embodiments, the vibration model may determine the natural vibration frequency based on the properties of the computing device 400, such as the mass of the 422, the number of fasteners 424, the material of the fasteners 424, any other property of the computing device 400, and combinations thereof.

In some embodiments, as discussed in further detail herein, the natural vibration frequency of the thermal management device 422 may be determined experimentally. For example, the natural vibration frequency may be determined using one or more sensors connected to the base 404, the thermal management device 422, the processor 420, or other portion of the computing device 400.

After determining the natural vibration frequency, the operator determines the tuned frequency of the tuned mass dampener 406. For example, the operator may determine the tuned frequency to be the same as or approximately the same as the natural vibration frequency of the thermal management device 422. In some embodiments, to determine the tuned frequency, the operator determines the dampener properties. For example, to determine the tuned frequency, the operator may determine the support dimensions of the tuning support 428 (e.g., the support height 430 and/or the support width 432). In some examples, to determine the tuned frequency, the operator may determine the mass of the tuning mass 426.

In some embodiments, the operator may prepare, assemble, or manufacture the tuned mass dampener 406 having the tuned frequency. For example, the operator may prepare, assemble, or manufacture the tuned mass dampener 406 having the support dimensions of the tuning support 428 (e.g., the support height 430 and/or the support width 432). In some examples, the operator may prepare, assemble, or manufacture the tuned mass dampener 406 having the mass of the tuning mass 426. In some embodiments, the mass of the tuning mass 426 may be changed while the support dimensions remain the same. In some embodiments, the mass of the tuning mass 426 may remain the same while the support dimensions are changed. The operator may secure the tuned mass dampener 406 to the base 404. In this manner, the operator may reduce or prevent damage to the thermal management device 422 due to vibrational motion.

In some embodiments, the operator may determine the tuned frequency for the tuned mass dampener 406 for a single computing device 400. For example, each computing device 400 and/or thermal management device 422 may be analyzed for the natural vibration frequency and the operator may determine the tuned frequency for the tuned mass dampener 406 that is tailored to the individual computing device 400 and/or thermal management device 422. In this manner, the tuned frequency may be as close as possible to the natural vibration frequency, thereby reducing the magnitude of the displacement of the thermal management device 422.

In some embodiments, the operator may determine the tuned frequency for a tuned mass dampener 406 to be installed on multiple computing devices 400. For example, a manufacturing run of computing devices 400 may include hundreds, thousands, tens of thousands, hundreds of thousands, millions, or more of the computing devices 400. Differences in dimensions and other variables caused by manufacturing tolerances may result in a variation in the natural vibration frequencies of the computing devices 400. The tuned frequency of the tuned mass dampener 406 may be determined to reduce the displacement magnitude of the thermal management device 422 of all or multiple of the computing devices 400. For example, the tuned frequency of the tuned mass dampener 406 may be within the frequency percentage of the natural vibration frequency of the thermal management device 422. This may help to reduce or prevent damage to multiple computing devices 400 and/or thermal management devices 422.

FIG. 5 is a representation of a side-view of a computing device 500, according to at least one embodiment of the present disclosure. A processor 520 is connected to a base 504. A thermal management device 522 is thermally connected to the one or more processors 520. The thermal management device 522 may be secured to the base 504 with one or more fasteners 524.

In accordance with at least one embodiment of the present disclosure, a tuned mass dampener 506 may be secured to the computing device 500. As the computing device 500 vibrates, the connection between the base 504 and the tuned mass dampener 506 may cause the tuned mass dampener 506 to vibrate, which may dampen the vibrations on the thermal management device 522.

In the embodiment shown, the tuned mass dampener 506 is located adjacent to the thermal management device 522. The thermal management device 522 may include one or more heat radiation fins 534. The heat radiation fins 534 be thermally connected to the thermal management device 522. The heat radiation fins 534 may absorb heat transferred to the thermal management device 522 by the processor 520. The heat radiation fins 534 may increase the surface area of the thermal management device 522. This may help to increase the rate at which heat is removed from the thermal management device 522.

In accordance with at least one embodiment of the present disclosure, the tuned mass dampener 506 may be located within the heat radiation fins 534. For example, one or more of the heat radiation fins 534 may be removed, shortened, or carved out to make room for the tuned mass dampener 506. Placing the tuned mass dampener 506 within the thermal management device 522 may make room for the tuned mass dampener 506 without rearranging or displacing any other computing component.

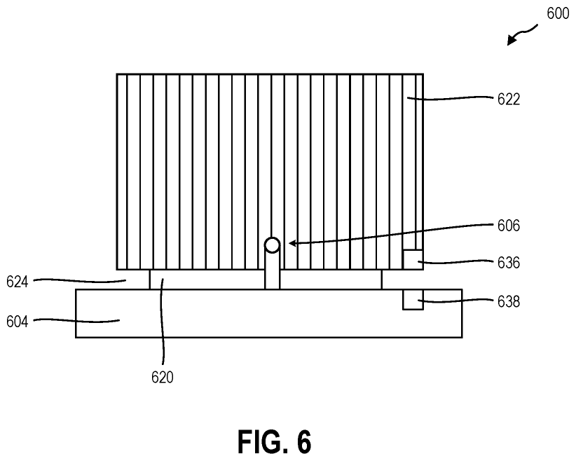

FIG. 6 is a representation of a side-view of a computing device 600, according to at least one embodiment of the present disclosure. A processor 620 is connected to a base 604. A thermal management device 622 is thermally connected to the one or more processors 620. The thermal management device 622 may be secured to the base 604 with one or more fasteners 624.

In accordance with at least one embodiment of the present disclosure, a tuned mass dampener 606 may be secured to the computing device 600. As the computing device 600 vibrates, the connection between the base 604 and the tuned mass dampener 606 may cause the tuned mass dampener 606 to vibrate, which may dampen the vibrations on the thermal management device 622.

As discussed herein, an operator may determine the natural vibration frequency of the thermal management device 622. In some embodiment, the operator determines the natural vibration frequency experimentally. For example, the operator may vibrate the computing device 600 through a range of frequencies. The computing device 600 may include a device vibration sensor 636 connected to the thermal management device 622 and a base vibration sensor 638 connected to the base 604. A vibration monitoring system may review the measurements from the device vibration sensor 636 and the base vibration sensor 638. The vibration monitoring system may identify resonant frequencies of the thermal management device 622 to determine the natural vibration frequency.

As discussed herein, the natural vibration frequency may be determined for a sample computing device 600 from a manufacturing run of the computing device 600. The sample computing device 600 may be representative of the rest of the computing devices from the manufacturing run. In this manner, if the sample computing device 600 breaks during testing, the determined natural vibration frequency may be applicable to the other computing devices 600 of the manufacturing run.

As discussed herein, the operator may use the determined natural vibration frequency to determine the tuned frequency of the tuned mass dampener 606. The operator may design the tuned mass dampener 606 to have the determined tuned frequency. In some embodiments, the tuned mass dampener 606 having the determined tuned frequency may be installed on the computing devices 600 from the manufacturing run that may have similar natural vibration frequencies as the sample computing device 600.

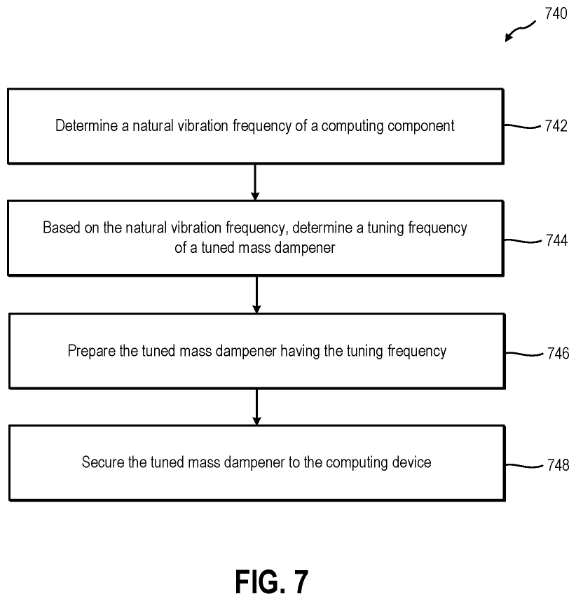

FIG. 7 is a flowchart of a method 740 for manufacturing a computing device, according to at least one embodiment of the present disclosure. A vibration reduction system may determine a natural vibration frequency of a computing component at 742. The computing component may be secured to a base. As discussed herein, the vibration reduction system may determine the natural vibration frequency in any manner. For example, the vibration reduction system may determine the natural vibration frequency using a vibration model. The vibration model may simulate vibration of the computing device based on the mass, size, connection, and other elements of the computing system. In some examples, the vibration reduction system may determine the natural vibration frequency using one or more vibration sensors. The vibration sensors may identify the magnitude of the displacement at various frequencies to determine the natural vibration frequency.

In some embodiments, the vibration reduction system may determine an operating vibration frequency. For example, the vibration reduction system may determine an operating vibration frequency during one or more of packaging, shipping, handling, operation, or other operations of the computing device. In some embodiments, the vibration reduction system may determine whether the operating vibration frequency overlaps the natural vibration frequency. If the operating vibration frequency overlaps the natural vibration frequency, then the vibration reduction system may prepare and secure a tuned mass dampener to the computing device.

The vibration reduction system may, based on the natural vibration frequency, determine a tuning frequency of a tuned mass damper at 744. The tuning frequency may be the same as or approximately the same as the natural vibration frequency. In some embodiments, the tuning frequency may be within a frequency percentage of the natural vibration frequency. In some embodiments, the tuning frequency may be determined using an average natural vibration frequency of a plurality of computing components or a plurality of computing devices. In some embodiments, the average natural vibration frequency may be based on manufacturing tolerances of the computing device.

The vibration reduction system may prepare the tuned mass dampener having the tuning frequency at 746. In some embodiments, preparing the tuned mass dampener may include determining the dimensions of the tuned mass dampener and/or the mass of the vibrating mass. In some embodiments, preparing the tuned mass dampener may include manufacturing and/or assembling the tuned mass dampener. In some embodiments, the tuned mass dampener may be secured to the computing device at 748. In some embodiments, the tuned mass dampener may be secured to the base of the computing device. In some embodiments, the tuned mass dampener may be secured to the computing component. In some embodiments, the tuned mass dampener may be secured to the computing device within heat radiation fins of a thermal management device.

One or more specific embodiments of the present disclosure are described herein. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A computing system, comprising:
a base;
a computing component connected to the base, the computing component having a vibration frequency; and
a tuned mass dampener having a tuned frequency to reduce a magnitude of vibration of the computing component.

2. The computing system of claim 1, wherein the tuned mass dampener includes a tuning mass connected to a tuning support.

3. The computing system of claim 1, wherein the tuned mass dampener is connected to the base.

4. The computing system of claim 1, wherein the computing component is a thermal management device.

5. The computing system of claim 4, wherein the thermal management device includes heat radiation fins, and wherein the tuned mass dampener is located within the heat radiation fins.

6. The computing system of claim 1, wherein the tuned frequency is approximately the same as the vibration frequency.

7. The computing system of claim 1, wherein the tuned frequency is within 20% of the vibration frequency.

8. A method of manufacturing a computing device, comprising:
determining a natural vibration frequency of a computing component secured to a base;
based on the natural vibration frequency, determining a tuning frequency of a tuned mass dampener;
preparing the tuned mass dampener having the tuning frequency; and
securing the tuned mass dampener to the computing device.

9. The method of claim 8, wherein determining the tuning frequency includes determining a support height, a support width, and a mass of a vibrating mass.

10. The method of claim 9, wherein preparing the tuned mass dampener includes preparing the tuned mass dampener having the support height, the support width, and the mass of the vibrating mass.

11. The method of claim 8, wherein determining the natural vibration frequency includes determining a threshold displacement, and wherein determining the tuning frequency includes determining a support height, a support width, and a mass of a vibrating mass to reduce a magnitude of a displacement of the computing component to below a threshold displacement.

12. The method of claim 8, wherein securing the tuned mass dampener to the computing device includes securing the tuned mass dampener to a base of the computing device.

13. The method of claim 12, wherein securing the tuned mass dampener to the base of the computing device includes securing the tuned mass dampener to the base within heat radiation fins of a thermal management device.

14. The method of claim 8, further comprising determining an operating vibration frequency.

15. The method of claim 14, wherein preparing the tuned mass dampener includes preparing the tuned mass dampener when the operating vibration frequency overlaps the natural vibration frequency.

16. The method of claim 8, wherein determining the natural vibration frequency includes modeling the natural vibration frequency in a vibration model.

17. The method of claim 8, wherein determining the natural vibration frequency includes testing a sample computing device using one or more vibration sensors.

18. A vibration reduction system for a computing system, comprising:
a base;
a thermal management device secured to the base, the thermal management device having a vibration profile; and
a tuned mass dampener including:
a support; and
a tuning mass connected to the support, the support having support dimensions and the tuning mass having a mass to dampen a magnitude of a displacement of the thermal management device.

19. The vibration reduction system of claim 18, wherein the tuned mass dampener is located within heat radiation fins of the thermal management device.

20. The vibration reduction system of claim 18, further comprising a first vibration sensor connected to the base and a second vibration sensor connected to the thermal management device.
